(19) United States
(12) Patent Application Publication
(10) Pub. No.: US 2002/0182778 A1
(43) Pub. Date: Dec. 5, 2002

(54) Flexible package fabrication method

(76) Inventors: Pei-Wei Wang, Taipei (TW); Chin-Jung Chang, Taipei Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/865,417

(22) Filed: May 29, 2001

(51) Int. Cl. H01L 21/50

(52) U.S. Cl. 438/119; 438/106

(57) ABSTRACT

A flexible package fabrication method, which enables the IC chip packaging film and the inner lead automated bonding to be simultaneously done. The method includes the steps of preparing a base member, electroplating a circuit having inner leads, outer leads, test lines/test terminals on the base member, covering the top side of the circuit with a polyimide passivation film or layer of flexible solder protective paint, bonding the bumps of a bumped IC chip or passive element to the inner leads of the circuit by thermocompression bonding, removing the base member, and covering the bottom side of the circuit with a polyimide passivation layer or layer of flexible solder protective paint.

### BACKGROUND OF THE INVENTION

The present invention relates to semiconductor packaging and, more specifically, to a flexible package fabrication method, which enables the IC chip packaging film and the inner lead automated bonding to be simultaneously done.

In order to protect IC components against damage or interference of external environments, various high-density packaging techniques have been developed, for example, CSP (chip scale package). An IC component must be connected to the circuit of the packaging structure to achieve the designed function. In a semiconductor packaging structure, the connection of electric circuit greatly affects the performance of the IC component.

In a variety of IC component circuit connection techniques, TAB (tape automated bonding) has been intensively used in VLSI (very large scale integration), high-speed electronic component package, aeronautic engineering, medical science, and a variety of electronic consumer products for the advantages of high circuit connection density (narrow lead pitch), automated bonding, pre-assembly electricity test, and low manufacturing cost.

The fabrication flow of TAB (tape automated bonding) includes the steps of (1) preparing a traced tape carrier by coating a copper membrane on a PI (polyimide) tape and then processing the copper membrane with photo masking and etching processes to form sprocket, device hole, and metal lead pattern on the PI tape, (2) processing the IC component (chip) with a bumping process, (3) connecting the IC chip obtained from step (2) to the tape carrier obtained from step (1) to complete ILB (inner lead bonding), (4) starting sealing process and then performing electric property tests, (5) attaching outer leads to the component to be driven to achieve OLB (outer lead bonding), and (6) proceeding final integrated tests.

In the aforesaid fabrication flow, the procedure of inner lead bonding is the key point to decide normal operation of the IC chip. Because the lead pitch is tiny, it is difficult to complete the fabrication. Therefore, the improvement of inner lead bonding technique determines the mass application of TAP (tape automated bonding).

FIGS. 1A and 1B are sectional views showing the inner lead bonding procedure of TAB (tape automated bonding) technique according to the prior art. As illustrated, a tape carrier 15 comprised of a PI (polyimide) tape 155 and a plurality of leads 153. Leads 153 are formed on the PI tape 155 by etching, each having a part protruded out of the PI (polyimide) tape 155. An IC chip 11 is provided, comprising a plurality of die pads 113 disposed at the top surface thereof and a passivation layer 115 covered on the top surface over the die pads 113. The die pads 113 each comprise a bump 13 penetrated through the passivation layer 115 to the outside for the connection of an external circuit. Thereafter, the leads 153 are respectively attached to the bump 13 of each of the die pads 113, and then bonded thereto by means of the application of a bonding apparatus, for example, a heat press 17 to complete ILB (inner lead bonding).

However, in the inner lead bonding of the aforesaid prior art TAB (tape automated bonding) technique, the leads 153 tend to be curved by external force because of their thin width, resulting in alignment difficulty. Because the bump 13 of each die pad 113 may have a different height, the height of the bump 13 of each die pad 113 must be controlled within a small tolerance. Significant height difference between the bump 13 of each of the die pads 113 affects the bonding reliability and the product quality. During bonding, heat and pressure must be accurately evenly applied to the bump 13 of each die pad 113 and the leads 153 to achieve high quality of bonding. Furthermore, the clearness of the solder paste applied to the bump 13 of each die pad 113 and the leads 153 is an important factor that determines the bonding quality.

In order to eliminate the aforesaid drawbacks, COF (chip on film) flexible chip module technique is developed. In comparison with TAB technique, a COF flexible chip module has the characteristics of being lighter and thinner with smaller lead pitch.

FIGS. 2A and 2B are sectional views showing the inner lead bonding procedure of COF (chip on film) technique. As illustrated, a flexible film 25 is prepared. The flexible film 25 comprises a PI (polyimide) tape 255 and a plurality of metal leads 253. The leads 253 are disposed at the bottom surface of the PI tape 255. Further, an IC chip 21 is prepared. The IC chip 21 comprises a plurality of die pads 213 disposed at the top surface thereof and a passivation layer 215 covered on the top surface over the die pads 213. The die pads 213 each comprise a bump 23 penetrated through the passivation layer 215 to the outside for the connection of an external circuit. The flexible film 25 further comprises a layer of ACF (anti-isotropic conductive film) or ACP (Anti-isotropic conductive paste) 257 covered on the bottom surface of the PI tape 255 over the leads 253. The leads 253 of the flexible film 25 are respectively aimed at the bump 23 of each of the die pads 213, and then bonded thereto by a bonding tool (heat press) 27. When finished, the die pads 213 are electrically connected to the leads 253 through the conductive layer 257 (see FIG. 2B).

In the aforesaid COF process, the key point is the bonding between the leads 253 and the bump 23 of each of the die pads 213. Because the leads have a tiny width and the thickness of the PI tape 255 is smaller than the PI (polyimide) tape 155 used in the tape carrier 15 of the aforesaid TAB technique, the leads tend to displace when heated, resulting in alignment difficulty. This process cannot get free from the effect of the factors of different heights of the bump 23 of each die pad 213, even application of pressure and heat to the IC chip 21 and the bump 23 of each die pad 213. Furthermore, the manufacturing cost of the flexible film 25 is higher than the aforesaid TAB process. Due to the aforesaid drawbacks, this COF process is not intensively used in mass production.

Because the PI film used for the tape carrier of the TAB technique or the flexible film of the COF technique is flexible, the element alignment is critical during inner lead bonding process. This critical element alignment requirement greatly complicates the fabrication procedure, and increases the manufacturing cost.

### SUMMARY OF THE INVENTION

The present invention has been accomplished to provide a flexible package fabrication method, which eliminates the drawbacks of the aforesaid TAB and COF packaging processes. It is the main object of the present invention to provide a flexible package fabrication method, which enables the fabrication of the flexible base plate and the inner lead bonding to be simultaneously performed, so as to simplify the fabrication procedure and to save the manufacturing cost. It is another object of the present invention to provide a flexible package fabrication method, which is able to employ an electroplating process to make the circuit subject to the desired pattern, so as to greatly improve the wiring density of the flexible IC chip module of COF or TAB technique than the etching method used in the prior art designs. It is still another object of the present invention to provide a flexible package fabrication method, in which the automated bonding of the inner leads and the IC chip and the fabrication of the tape carrier are processed under the support of a base member of relatively higher hardness, so that the bumps of the IC chip inner leads can be accurately aimed at the inner leads and the yield of the fabrication can be relatively increased. It is still another object of the present invention to provide a flexible package fabrication method, which enables the bonding of the inner leads with the bumps of the IC chip to be performed by means of the use of a conventional IC chip bonding machine, so that the productivity can be greatly increased, and the manufacturing cost can be relatively reduced.

### BRIEF DESCRIPTION OF THE DRAWINGS

FIGS. 1A and 1B are sectional views showing the inner lead bonding of conventional TAB (tape automated bonding) technique.

FIGS. 2A and 2B are sectional views showing the inner lead bonding of conventional COF (chip on film) technique.

FIGS. from 3A through 3E illustrate the simultaneous fabrication of flexible package and inner lead bonding according to the present invention.

FIG. 4 shows an alternate form of the flexible package according to the present invention.

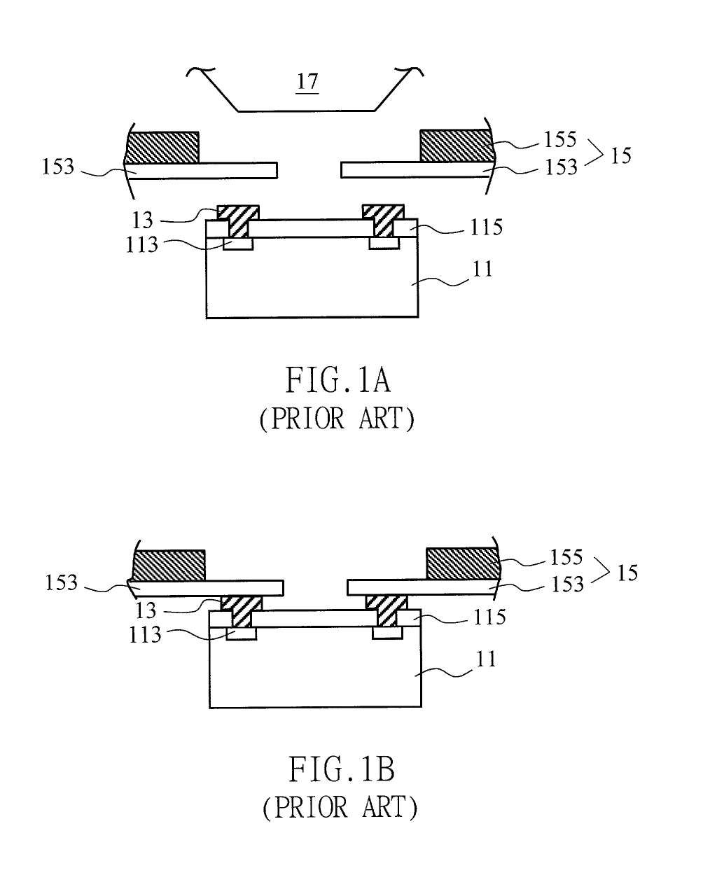

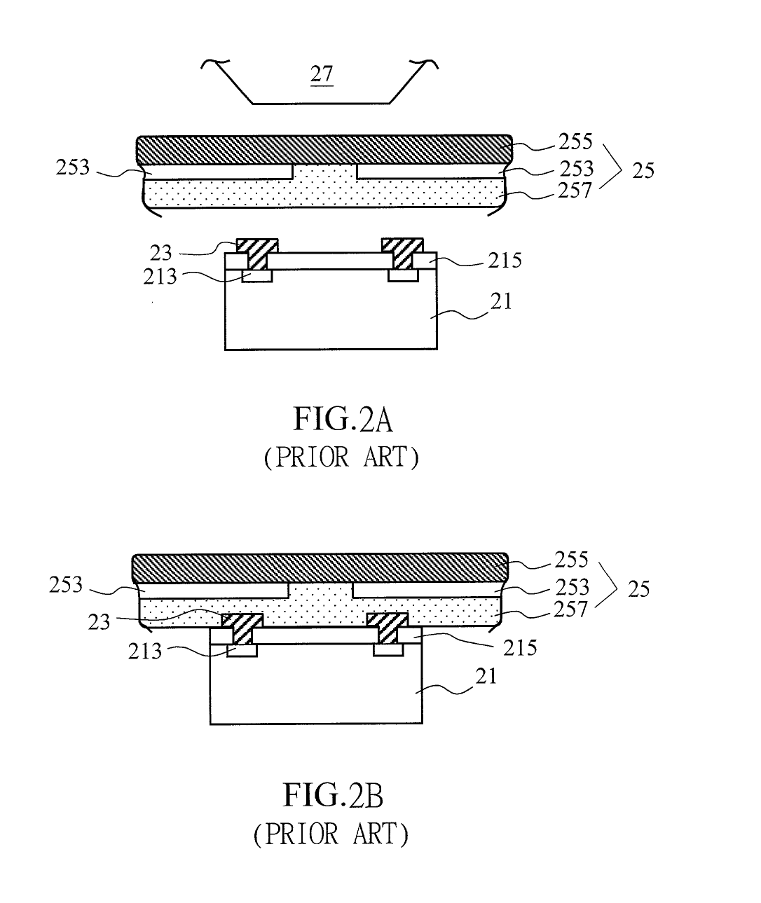

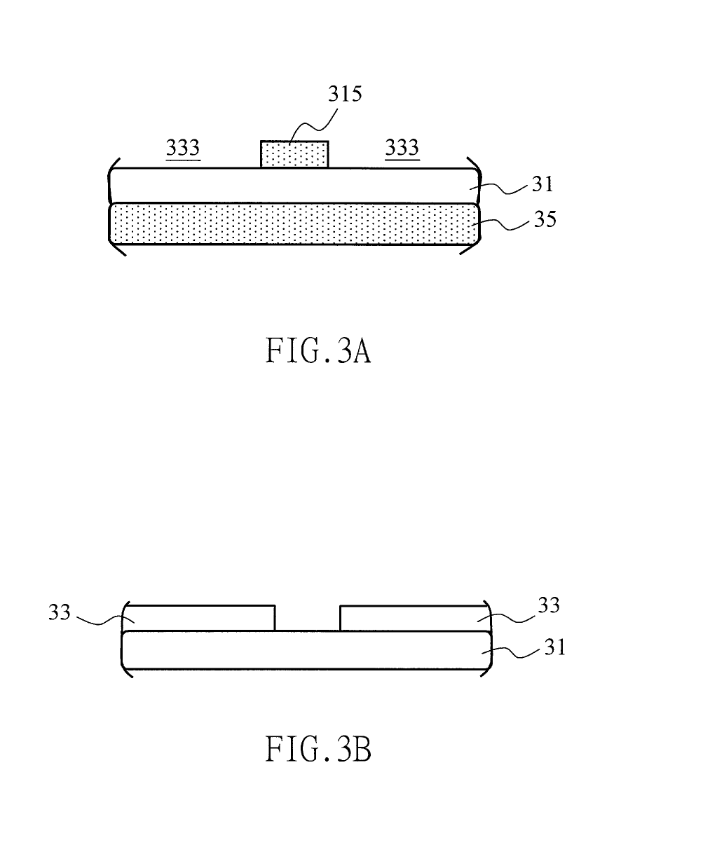

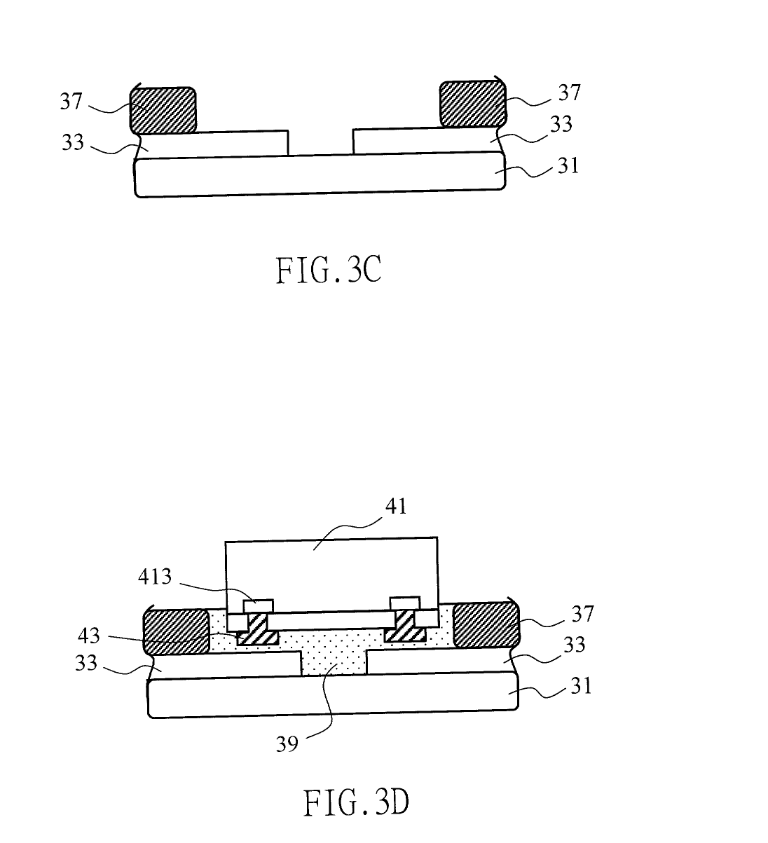

FIGS. from 5A through 5D illustrate the fabrication of a tape carrier according to the present invention.

### DETAILED DESCRIPTION OF THE PREFERRED EMBODIMENT

A flexible package fabrication method in accordance with the present invention is described hereinafter with reference to FIGS. from 3A through 3E.

The first step of the method is to prepare a base member 31 made of copper, aluminum, iron, nickel, zinc, steel, or stainless steel, or their composition, and then to scheme circuit positions 333 on a part of the top surface of the base member 31 for inner leads, lead shoulder, outer leads, passive element die pads, test lines or test terminals, and then to cover the top surface of the base member 31 with a layer of photo-resisting coating 315 beyond the schemed area, and then to cover the bottom surface of the base member 31 with a layer of stripping material 35 adapted to isolate electroplating material (see FIG. 3A). The photo-resisting coating 315 can be selected from dry film or liquid state photo-resisting material.

The second step of the method is to coat the top surface of the base member 31 with at least one metal layers by means of electroplating or etching, so as to form a circuit 33 having the desired inner leads, lead shoulders, outer leads, passive element die pads, and test lines/test terminals, and then to remove the photo-resisting coating 315 and the stripping covering 35 from the base member 31 (see FIG. 3B). The circuit 33 can have a single layer structure or multi-layer structure made of material good for bonding to the bumps of the IC chip and not strippable with the base member 31. Preferably, the material for the circuit 33 is selected from gold, nickel, copper, palladium, platinum, tungsten, nickel-gold, palladium-nickel, titanium-palladium-gold, titanium-palladium-gold, chrome-nickel-gold, titanium-tungsten-gold, or their composition.

The third step of the method is to adhere a protective layer 37 to the top surface of the inner leads 33, keeping a part of each of the inner leads 33 exposed outside the protective layer 37 for further IC chip installation (see FIG. 3C). The protective layer 37 is a polymeric plastic film preferably made of polyimide, epoxy resin, polyester resin, or acrylic resin.

The fourth step of the method is to adhere a conductive layer of ACF (anti-isotropic conductive film) or ACP (Anti-isotropic conductive paste) 39 to the surface of the inner leads 33, and then to turn the bumped IC chip 41 or passive elements so as to aim the metal bumps 43 at the inner leads 33 respectively, and then to bond the metal bumps 43 and the inner leads 33, and then to employ post-cure and potting processes so as to achieve permanent connection between the bumps 43 and the inner leads 33. After the post-cure and potting processes, the IC chip (or passive element) 41 is electrically connected to the inner leads 33 through the die pads 413, the bumps 43, and the conductive layer 39 (see FIG. 3D).

The fifth step, namely, the last step is to remove the base member 31 by means of wet or dry etching, and then to fasten a flexible layer of solder protective paint (protective film) 45 to the bottom surface of the inner leads 33 by means of wet coating or dry-adhesion to protect the inner leads 33 (see FIG. 3E). The flexible layer of solder protective paint (protective film) 45 is preferably made of photosensitive or thermosetting epoxy resin or acrylic resin. During the formation of the solder protective paint 45, outer lead, test line or test terminal space is preserved, or tin/nickel/gold coating process is employed to the product to facilitate further outer lead, test line, or test terminal bonding operation. Thus, the fabrication of the film for flexible chip package and the bonding of inner leads are done.

Because the circuit fabrication and inner lead bonding processes are performed and achieved on a hard base, positioning and alignment can easily be achieved by means of the application of a regular chip-bonding machine when bonding to the IC chip. Further, using electroplating instead of conventional etching greatly improves the fabrication of microcircuit on flexible chip package film and the density of flexible chip module COF wiring.

The bonding of the inner leads 33 and the respective bumps 43 can be achieved by means of thermocompression bonding, ultrasonic bonding, thermosonic bonding, laser bonding, or solder reflow.

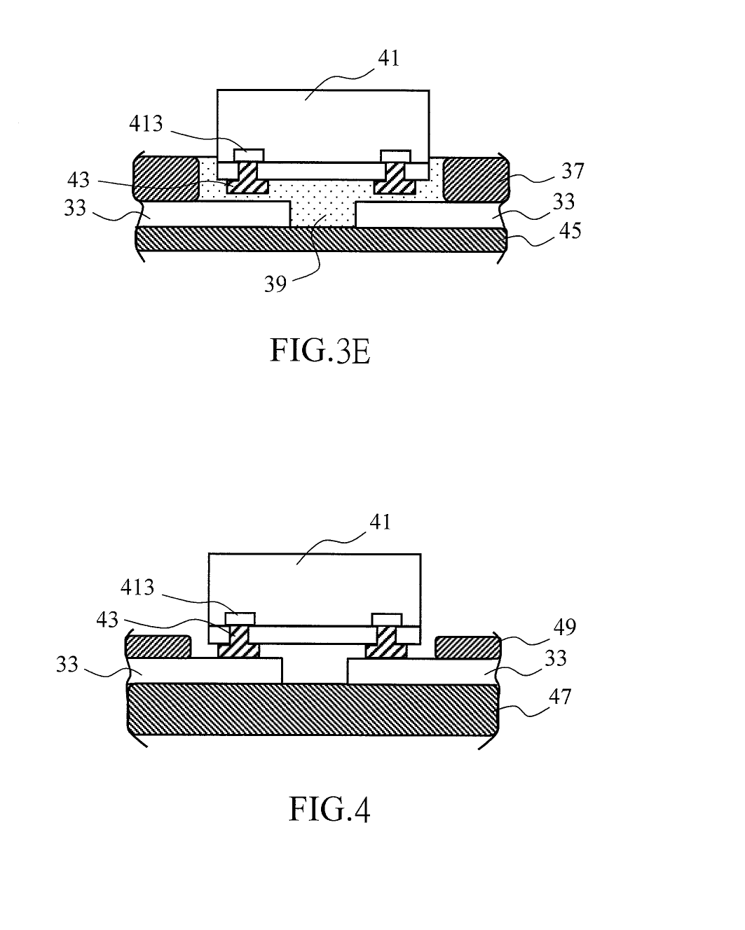

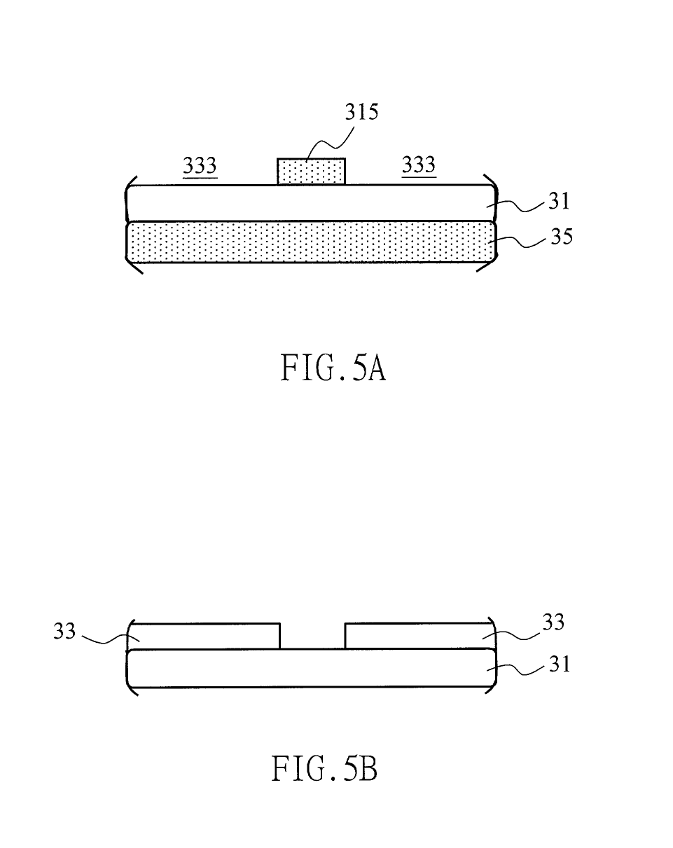

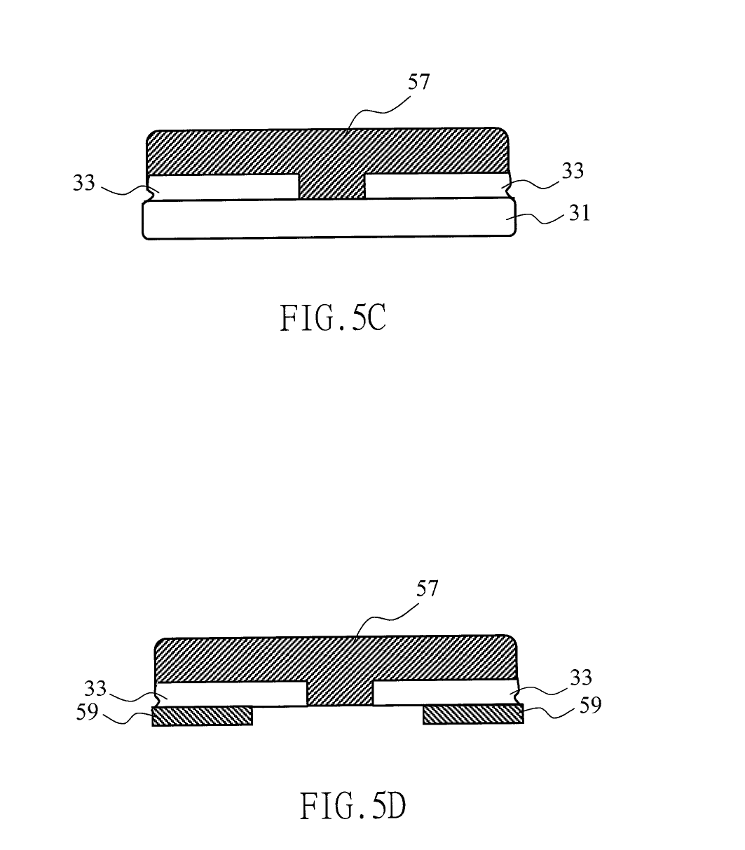

FIG. 4 shows an alternate form of the flexible package according to present invention. The technique of the present invention can also be used in TAB (tape automated bonding). In this case, the aforesaid conductive layer 39 is eliminated during the fourth step (3D), and the IC chip 41 is directly turned upside down to aim the respective bumps 43 at the inner leads 33, and then the posterior heating, compression, baking, and potting processes are proceeded one after another in proper order.

In the aforesaid embodiments, the protective layer 37 can be achieved by means of covering the top surface of the inner leads with a layer of solder protective paint 49 by wet coating or dry adhesion. The layer of solder protective paint 49 can be selected from photosensitive or thermosetting type flexible epoxy resin or acrylic resin. Alternatively, a passivation layer 47 made of polyimide, epoxy resin, polyester resin, or acrylic resin may be used instead of the solder protective paint 45 and fastened to the bottom surface of the leads 33 for protection.

FIGS. from 5A through 5D show the fabrication of a tape carrier of TAB according to the present invention. This method comprises the steps of:

a) preparing a base member 31, and then scheming a circuit location 333 on the top surface of the base member 31, and then coating with the top surface of the base member 31 a layer of photo-resisting material 315 beyond the schemed circuit location 333, and then covering the bottom surface of the base member 31 with a layer of stripping material 35 adapted to isolate electroplating material (see FIG. 5A);

b) forming at least one layer of metal coating on the top surface of the base member 31 by means of electroplating or etching, and then removing the layer of photo-resisting material 315 and the layer of stripping material 35 from the base member 31 so as to form a circuit 33 having inner leads, lead shoulders, outer leads, test lines/test terminals on the top surface of the base member 31 (see FIG. 5B);

c) covering the top surface of the base member 31 with a layer of protective material 57 over the circuit 33 by coating or press-bonding for protection (see FIG. 5C); and

d) removing the base member 31 by wet or dry etching, and then covering the bottom surface of the circuit 33 with a layer of protective paint 59 by means of wet coating or dry adhesive with an outer lead area left for further outer lead bonding operation (not shown) to finish the fabrication of the desired tape carrier (see FIG. 5D). The surface treatment of the inner and outer lead areas is achieved by electroplating the inner and outer lead areas with tin, nickel or gold to facilitate further inner and outer lead bonding operations.

As indicated above, the fabrication of the circuit 33 is proceeded and finished on a base member of relatively higher hardness, so that the process of electroplating is practical. Therefore, the invention greatly improves the fabrication of tape carrier circuit and its wiring density, and greatly reduces the manufacturing cost of the tape carrier.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A flexible package fabrication method comprising the steps of:
(A) preparing a base member having a top surface and a bottom surface;
(B) forming a circuit on a part of the top surface of said base member;
(C) preparing an IC chip having bumps, and aiming the bumps of said IC chip at said circuit, and bonding the bumps of said IC chip to said circuit; and
(D) removing said base member from said circuit and said IC chip, and forming a passivation layer on one side of said circuit.

2. The flexible package fabrication method of claim 1 further comprising the sub-step of forming a conductive layer on said circuit for the bonding of the bumps of said IC chip before the step (C).

3. The flexible package fabrication method of claim 2 wherein said conductive layer is selected from ACF (anti-isotropic conductive film), ACP (Anti-isotropic conductive paste), or their composition.

4. The flexible package fabrication method of claim 1 wherein the formation of said circuit includes the steps of:
(a) forming a photo-resisting layer on the top surface of said base member beyond pre-schemed area for said circuit;
(b) electroplating at least one metal layer on the top surface of said base member to form said circuit; and
(c) removing said photo-resisting layer from said base member.

5. The flexible package fabrication method of claim 1 wherein said circuit comprises at least one of inner leads, lead shoulders, outer leads, passive element die pads, test lines, test terminals, and their combination.

6. The flexible package fabrication method of claim 1 wheein said circuit is made of metal material selected from gold, nickel, copper, palladium, platinum, tungsten, nickel-gold, palladium-nickel, titanium-palladium-gold, titanium-palladium-gold, chrome-nickel-gold, titanium-tungsten-gold, and their composition.

7. The flexible package fabrication method of claim 1 further comprising the sub-step of forming a second protective layer of a part of an opposite side of said circuit.

8. The flexible package fabrication method of claim 7 wherein said second protective layer is a polymeric plastic film made of one of the materials of polyimide, epoxy resin, polyester material, and acrylic resin.

9. The flexible package fabrication method of claim 1 further comprising the step of forming a flexible layer of solder protective paint on a part of one side of said circuit opposite to said passivation layer.

10. The flexible package fabrication method of claim 9 wherein said flexible layer of solder protective paint is selectively made of one of the materials of epoxy resin and acrylic resin.

11. The flexible package fabrication method of claim 1 further comprising the step of forming a flexible layer of solder protective paint on a bottom surface of said circuit after removal of said base member.

12. The flexible package fabrication method of claim 1 further comprising the step of forming a stripping layer on the bottom surface of said base member before the formation of said circuit, and the step of removing said stripping layer after the formation of said circuit.

13. The flexible package fabrication method of claim 1 wherein said base member is made of material selected from copper, aluminum, iron, nickel, zinc, steel, stainless steel, and their composition.

14. A flexible package fabrication method comprising the steps of:
(a) preparing a base member having a top surface and a bottom surface;
(b) forming a circuit on a part of the top surface of said base member subject to a predetermined pattern;
(c) forming a passivation layer on said circuit;
(d) removing said base member and then forming a layer of solder protective paint on a part of one side of said circuit opposite to said passivation layer.

15. The flexible package fabrication method of claim 14 wherein the formation of said circuit includes the steps of:
(a) forming a photo-resisting layer on the top surface of said base member beyond pre-schemed area for said circuit;
(b) electroplating at least one metal layer on the top surface of said base member to form said circuit; and
(c) removing said photo-resisting layer from said base member.

16. The flexible package fabrication method of claim 14 wherein said circuit comprises at least one of inner leads, lead shoulders, outer leads, passive element die pads, test lines, test terminals, and their combination.

17. The flexible package fabrication method of claim 14 wherein said circuit is made of metal material selected from gold, nickel, copper, palladium, platinum, tungsten, nickel-gold, palladium-nickel, titanium-palladium-gold, titanium-palladium-gold, chrome-nickel-gold, titanium-tungsten-gold, and their composition.

18. The flexible package fabrication method of claim 14 wherein said passivation layer and said layer of solder protective paint are made of one of the polymeric materials of polyimide, epoxy resin, polyester material, acrylic resin, and their compound.

19. The flexible package fabrication method of claim 14 further comprising the step of forming a stripping layer on the bottom surface of said base member before the formation of said circuit, and the step of removing said stripping layer after the formation of said circuit.

20. The flexible package fabrication method of claim 14 wherein said base member is made of material selected from copper, aluminum, iron, nickel, zinc, steel, stainless steel, and their composition.
